(19) United States
(12) Patent Application Publication
(10) Pub. No.: US 2025/0140304 A1
(43) Pub. Date: May 1, 2025

(54) APPARATUSES AND METHODS FOR REDUCED POWER COMMAND SHIFTER

(71) Applicant: Micron Technology, Inc., Boise, ID (US)

(72) Inventors: Yukimi Morimoto, Sagamihara (JP); Takayuki Miyamoto, Tokyo (JP); Atsuko Momma, Tokyo (JP)

(73) Assignee: Micron Technology, Inc., Boise, ID (US)

(21) Appl. No.: 18/774,032

(22) Filed: Jul. 16, 2024

Related U.S. Application Data
(60) Provisional application No. 63/595,071, filed on Nov. 1, 2023.

(51) Int. Cl. G11C 11/4076; G11C 11/4093; G11C 11/4096

(52) U.S. Cl. CPC G11C 11/4076; G11C 11/4093; G11C 11/4096

(57) ABSTRACT

A memory device includes a command shifter which includes a latch array with latches coupled in series. After receiving a command the command passes through the latch array and a ready pulse is provided when the command exits the array. The latch array is divided into portions (e.g., rows) with each row receiving its own clock signal from a respective clock circuit. Each clock signal is toggling while the command is within that row of the latch array or about to enter that row. For example, when the command is within N latches of the end of the previous row of the latch array or when a setting and command signal indicates the command is about to initially enter the array in that row.

### CROSS REFERENCE TO RELATED APPLICATION(S)

This application claims the benefit under 35 U.S.C. § 119 of the earlier filing date of U.S. Provisional Application Ser. No. 63/595,071 filed Nov. 1, 2023, the entire contents of which is hereby incorporated by reference in its entirety for any purpose.

### BACKGROUND

Information may be stored on memory cells of a memory device. The memory cells may be organized at the intersection of word lines (rows) and bit lines (columns). During access operations, the memory accesses information in the memory cells for example to write new information to those memory cells as part of a write operation or to read information from the memory cells as part of a read operation.

In order to prevent conflicting commands, the memory may provide a pulse to indicate the memory is ready for the next command. The pulse may be provided a length of time after receiving a command, where the length of time is based on a setting of the memory device. A command shifter receives the access command and shifts the command through a number of latches based on the specified length of time. When the command leaves the command shifter, the pulse is provided. Since the command shifter may be active for a relatively long time, there may be a need to reduce the power consumption of the command shifter.

### BRIEF DESCRIPTION OF THE DRAWINGS

FIG. 1 is a block diagram of a memory system according to some embodiments of the present disclosure.

FIG. 2 is a block diagram of a command shifter according to some embodiments of the present disclosure.

FIG. 3 is a chart of example operations in a latch array of a command shifter according to some embodiments of the present disclosure.

FIG. 4 is a timing diagram of clock signals in a command shifter according to some embodiments of the present disclosure.

FIG. 5 is a schematic diagram of latches along a row of a command shifter according to some embodiments of the present disclosure.

FIGS. 6A-6C are schematic diagrams of clock circuits according to some embodiments of the present disclosure.

FIG. 7 is a timing chart of example signals in a row of a tWR command shifter according to some embodiments of the present disclosure.

FIG. 8 is a block diagram of a latch array according to some embodiments of the present disclosure.

FIG. 9 is a block diagram of a latch array according to some embodiments of the present disclosure.

FIGS. 10A-10B are schematic diagrams of clock circuits according to some embodiments of the present disclosure.

FIG. 11 is a timing diagram of operations in an tRTP shifter according to some embodiments of the present disclosure.

FIG. 12 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated (or opened) based on a row address and then selected memory cells along that active word line may have their information read or written to based on which bit lines are accessed, which may be based on a column address. When the access operation is over, the word line may be pre-charged to inactivate (or close) the word line.

The memory may have specific timing for a minimum amount of time between access operations. For example, a write recovery time tWR may be a minimum amount of time between when a memory bank receives a write command when the memory bank is available again. The read to pre-charge time tRTP may be a minimum amount of time between when the memory bank receives a read command and when the memory bank is available again. Times, such as tWR and tRTP may be specified in a number of clock cycles. The memory may provide a pulse after the specified amount of time since receiving the command, to indicate that the memory is ready for a next command, for example, an internally issued precharge. The specified amount of time may be a setting of the memory, for example as determined by one or more registers of a mode register.

The memory includes a command shifter which provides the pulse signal at a specified timing. The command shifter includes a number of latches coupled in series. The command enters a latch, and then passes to a next latch in the series based on activations (e.g., rising edges, falling edges, or combinations thereof) of a toggling of a clock signal. For example, the command may pass to a next latch in the series on each rising edge of a clock signal while the clock signal is toggling. A clock signal may be active or toggling when it is periodically changing between voltage levels. The clock signal may be inactive when it is held at a voltage level (e.g., when it is not toggling). While the command is in one of the latches of the command shifter, the busy signal is provided. When the command passes through a number of latches matching the specified time, the command exits the command shifter and the busy signal stops being provided. By controlling how many latches the command passes through, the timing of when the pulse signal is provided (to indicate the memory is ready for the next command) may be adjusted.

The command shifter may be relatively power intensive, since a toggling clock signal must be sent to a relatively large number of latch circuits for a relatively long amount of time. There may be a need to more efficiently manage the operation of the command shifter in order to reduce the number of latches which are receiving a toggling clock signal.

The present disclosure is drawn to apparatuses, systems, and methods for a reduced power command shifter. A command shifter of the present disclosure includes a number of latches coupled in series, which are divided into a number of portions. Each portion receives its own clock signal (e.g., a first clock for a first portion, a second clock for a second portion, etc.). Shortly before the command enters a first portion, the first clock begins toggling. When the command is within the last N latches of the first portion, the second clock begins toggling. In this manner, each clock signal begins toggling shortly before the command enters the portion associated with that clock signal, and at most two clock signals are toggling, each of which is driving only a portion of the latches in the command shifter. This may reduce power consumption since fewer latches are receiving toggling clock signals at a given time.

For example, the command shifter may be thought of as being a number of latches organized into rows and columns (which may or may not reflect the physical layout of the latches). Each row includes a number of latches coupled in common to a clock signal provided by a respective clock circuit for that row. The columns represent the individual latch circuits within the row. So the command may move across a row and then enter a next row. In general, each clock circuit receives busy signals from the latches of the row it is associated and the N final latches of the previous row. When one or more of the busy signals is active, that clock circuit provides a toggling clock signal to its row. As described in more detail herein, there may be variations between clock circuits associated with different rows. In this manner, each row may only receive a toggling clock signal when the command is within that row, or close to entering that row.

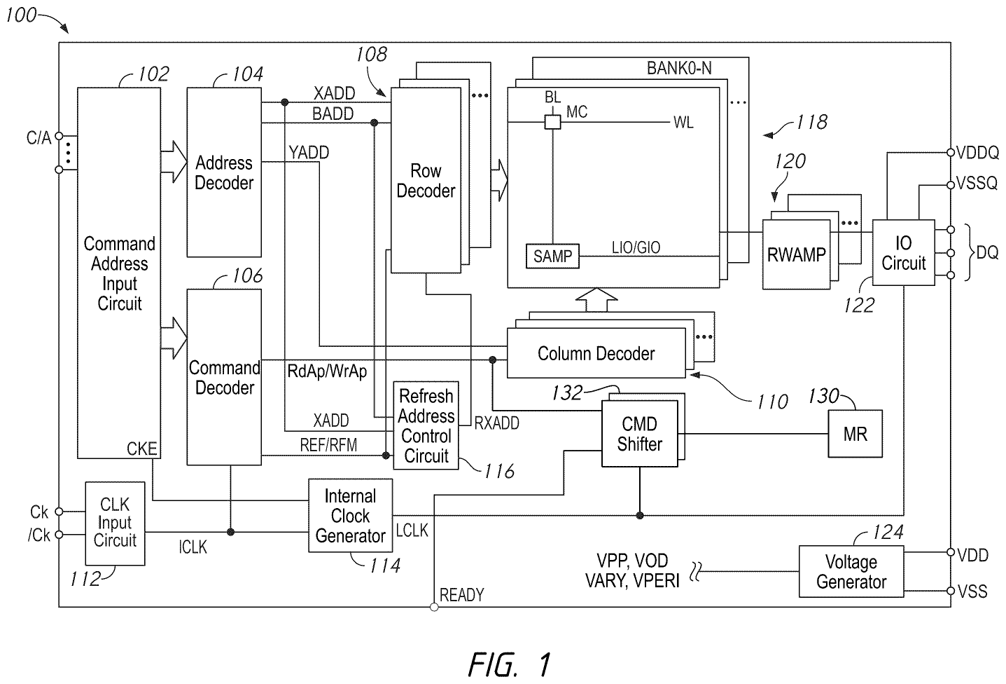

FIG. 1 is a block diagram of a semiconductor device according to at least one embodiment of the disclosure. The semiconductor device 100 may be a semiconductor memory device, such as a DRAM device integrated on a single semiconductor chip. The device 100 may be operated by a controller. The memory receives various commands, data, signals, and voltages (e.g., from the controller).

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL (rows), a plurality of bit lines BL (columns), and a plurality of memory cells MC arranged at intersections of the plurality of word lines WL and the plurality of bit lines BL. Each memory cell stores information. For example, the memory cell may be a capacitive element which stores a bit of information as an amount of charge on the capacitive element.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers 120 over local data lines (LIO) and global data lines (GIO). Conversely, write data outputted from the read/write amplifiers 120 is transferred to the sense amplifier SAMP over the GIO and LIO and amplified by the SAMP over the BL to the memory cell at the intersection with the active bit line.

The semiconductor device 100 may employ a plurality of external terminals. The external terminals include command and address (C/A) terminals along a command and address bus to receive commands and addresses. Other external terminals include clock terminals to receive clocks clock signals CK and/CK along a clock bus, data terminals DQ to send and receive data along a data bus, and power supply terminals to receive power supply potentials such as VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. For example, the clock signal LCLK may be a divided clock signal which is half the frequency of the external clocks CK and/CK. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

When a command is received, a command shifter circuit 132 provides a pulse READY a length of time after receiving the command, where the length of time is specified by a setting of the memory device 100. For example, the command shifter 132 may receive a read auto-precharge signal RdAp from the command decoder 106 and provide for the READY pulse a time tRTP after receiving the read signal, or may receive a write auto-precharge signal WrAp and provide for the READY pulse a time tWR after receiving the write signal. The command decoder 132 may measure the times tRTP or tWR based on a clock signal LCLK. The values of the tRTP and tWR may be set by settings, such as from a mode register 130.

The command shifter 132 includes a number of latches coupled in series. The command (e.g., read auto-precharge RdAp or write auto-precharge WrAp) is passed through the latches with timing based on a clock signal LCLK. As described in more detail herein, the command shifter 132 may generate a number of internal clock signals based off of LCLK, each of which may be selectively activated (e.g., set to toggling) as the command passes through a portion of the latches.

In some embodiments, there may be multiple command shifters 132. For example a first command shifter circuit for providing READY after tRTP and a second command shifter circuit for providing READY after tWR. In some embodiments, there may be different READY signals and different command shifters 132 for different banks of the memory.

As part of an example read auto-precharge operation, the device 100 may receive a read auto-precharge command RdAp along with memory addresses which indicate where the read command should be performed. Based on the read auto-precharge command RdAp, the pulse READY is provided at a time tRTP later by the command shifter 132. Responsive to the internal read command issued by auto-precharge command, data is read out from the memory cells of the bank specified by BADD at the intersection of the row specified by XADD and the columns specified by YADD. The read auto-precharge command is received by the command decoder 106, which provides internal read command so that read data from the memory array 118 is provided to the read/write amplifiers 120. The read data is output to the controller 150 from the data terminals DQ via the input/output circuit 122. Upon receiving the pulse READY, Command Decoder 106 issues an internal precharge command and Address Decoder 104 chooses the associated BADD.

As part of an example write auto-precharge operation, the device 100 may receive a write auto-precharge command WrAp along with memory addresses which indicate where the write command should be performed. Based on the write auto-precharge command WrAp, the pulse READY is provided at a time tWr later by the command shifter 132. As part of the write auto-precharge command, data is received along the DQ terminals and is passed through the IO circuit 122 and RW amplifiers 120 to the memory array 118. The write auto-precharge command is received by the command decoder 106, which provides internal write command so that the data is written to memory cells in the bank specified by BADD at the intersection of the row specified by XADD and the column(s) specified by YADD. Upon receiving the pulse READY, the command decoder 106 issues an internal precharge command and the address decoder 104 chooses the associated BADD.

The device 100 may also receive commands causing it to carry out refresh operations. A refresh control circuit 116 may generate refresh address RXADD and the row decoder may refresh the word lines associated with that refresh address RXADD. The memory device 100 may receive a refresh signal REF and perform one or more refresh operations responsive to the refresh signal. In some embodiments, the refresh control circuit 116 may perform different types of refresh operations. For example, the refresh control circuit 116 may perform ‘normal’ refresh operations where the refresh address RXADD is generated using sequence logic, for example to count through the row addresses or the refresh control circuit 116 may perform targeted refresh operations on specific addresses (e.g., the victims of an identified aggressor).

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

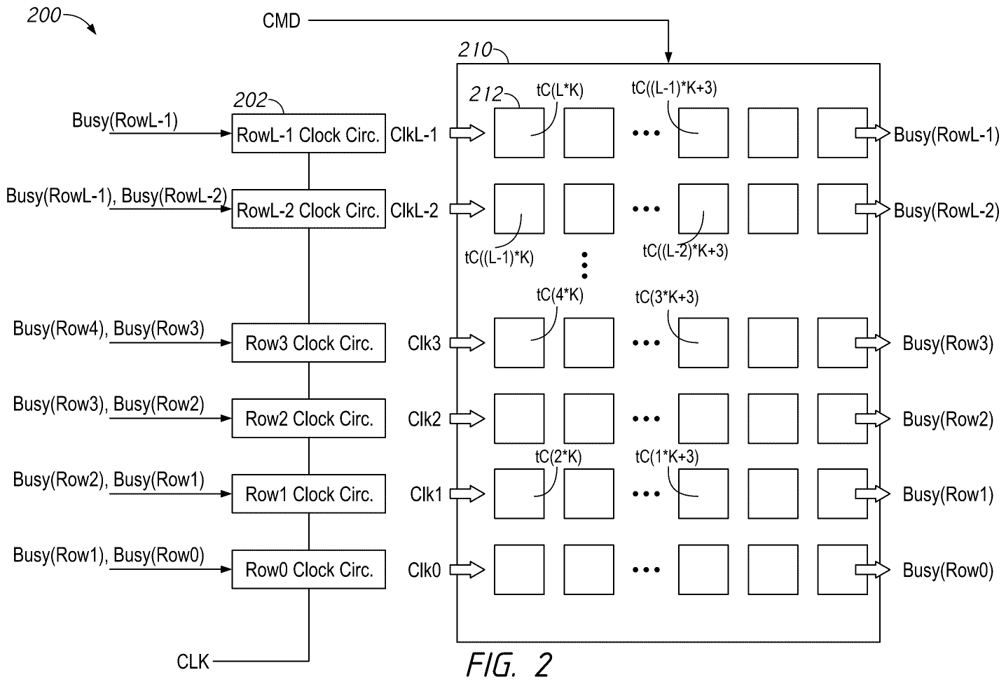

FIG. 2 is a block diagram of a command shifter according to some embodiments of the present disclosure. The command shifter 200 of FIG. 2 may, in some embodiments, implement the command shifter 132 of FIG. 1. The command shifter 200 includes an array 210 of latch circuits 212. A command CMD (e.g., a read auto-precharge command RdAp or a write auto-precharge command WrAp) enters the command shifter and passes through a number of the latch circuits 212 based on a setting (e.g., from a mode register). Each latch circuit 212 provides a busy signal when the command is in that latch. The command shifter 200 includes a number of clock circuits 202, each of which provides a clock signal to a respective portion of the latch array 210. The clock circuits 202 may provide a toggling to clock signal to their respective portion when the command is within that portion, or close to entering that portion, for example within N latches of the end of a previous portion or about to initially the array 210 in a latch of that portion. When the command CMD exits a final latch of the array 210, a ready pulse signal READY is provided to indicate that the device is ready for a next command and/or to trigger the auto-precharge operation.

The latch array 210 includes a number of individual latch circuits 210. As shown in FIG. 2, the latches 212 of the array 210 may be organized into a grid of rows and columns. This may represent a logical organization of latches 212 in the array 210. In some embodiments, the physical latch circuits may be laid out in a grid format as well. In other embodiments, the latches may have a different arrangement. Each box shown in the array 210 represents a different latch circuit 212. In the example layout of FIG. 2, there are L rows of latches, each of which includes K latch circuits, for a total of L×K latches in the array 210. While each row is shown as having a same number of latches in the example of FIG. 2, other example embodiments may have different numbers of latches in different rows.

The latch circuits 212 are coupled in series, such that an output of a first latch circuit is an input of the next latch circuit. In the example layout of FIG. 2, the series may be generally coupled from left to right and top to bottom. For example, the top left most latch circuit provides an output to the next latch circuit to its right in the same row and so forth. The last latch circuit in each row may be coupled to a first latch circuit in the next row. Other organizations of the series of latches may be used in other example embodiments. However, for the sake of consistency, the various latch arrays, and portions thereof, described herein will generally be assumed to be set up in a similar fashion, where the command passes from left to right along a row and then to the left most latch of the next row from top to bottom, unless otherwise noted.

The command CMD enters the array at a latch circuit 212 specified by a setting of the memory (e.g., a mode register setting). The settings represent a command delay time tC, which is the time after receiving the command CMD that the command shifter 200 provides the ready pulse READY. The delay time tC may have multiple different possible values, each of which represents a number of clock cycles which the command CMD is shifted through the array 210. For example the delay time tC may represent tRTP (if the command is RdAp) or tWR (if the command CMD is WrAp). In the example of FIG. 2, the value of tC determines at which latch circuit 212 in the array 210 the command enters the array 210. The less time that tC represents (e.g., the fewer clock cycles) then the closer to the end of the latch series of the array 210 the command will start. Several example values of tC are shown throughout the array 210, shown superimposed on the box which represents the latch where the command CMD would enter if tC has that setting. Other arrangements of the array are also possible. For example, there may be an initial row of latches which the command must always pass through before jumping to a latch specified by tC in other example embodiments.

Each row of the array 210 receives a respective clock signal from a respective clock circuit 202. For example, RowL-1 receives a clock signal ClkL-1 from a RowL-1 clock circuit 202, RowL-2 receives a clock signal ClkL-2 from a RowL-2 clock circuit 202 and so forth. Each row also provides a set of busy signals, so RowL-1 provides busy signals Busy(RowL-1), the RowL-2 provides busy signals Busy(RowL-2) and so forth. The busy signals from a given row may include a busy signal from each latch circuit 212 of that row. For example, if there are K latches per row, then each set of busy signals may be Busy<K-1:0>.

Each clock circuit 202 (except the first) receives the busy signals from its own row and one or more of the busy signals from the previous row. For example, the clock circuit of row 2 may receive the busy signals Busy(Row2) and one or more bits of Busy(Row3). The number of bits from the previous row may vary from embodiment to embodiment. For example if the set of busy signals from a row is K bits long, then the clock circuit of the next row may receive the final N bits. In other words, each clock circuit 202 may receive every bit of the same row and the final N bits of the previous row. For example, the clock circuit of row2 may receive Busy (Row3)<N-1:0> and Busy(Row2)<K-1:0>. In other words the clock circuit 202 may receive a signal which indicates when the command is within its own row or within the final N latches of the previous row.

The clock circuits 202 also receive a clock signal CLK (e.g., LCLK of FIG. 1). When one of the bits of the busy signals coupled to that clock circuit 202 is active, the clock circuit 202 provides the clock signal CLK as the respective row clock signal. When the clock signal CLK is provided as the row clock signal, the row clock signal is toggling, activating the latches along that row. In this way, each row receives a toggling clock signal when the command is within that row or passing through the final N latches of the previous row in the array 210.

In some embodiments, one or more rows may be disabled based on settings of the memory. For example, if the setting tC specifies tC(3*K+3), then the clock circuits for rows 4 to L-1 may be disabled, since the command will not pass through those rows.

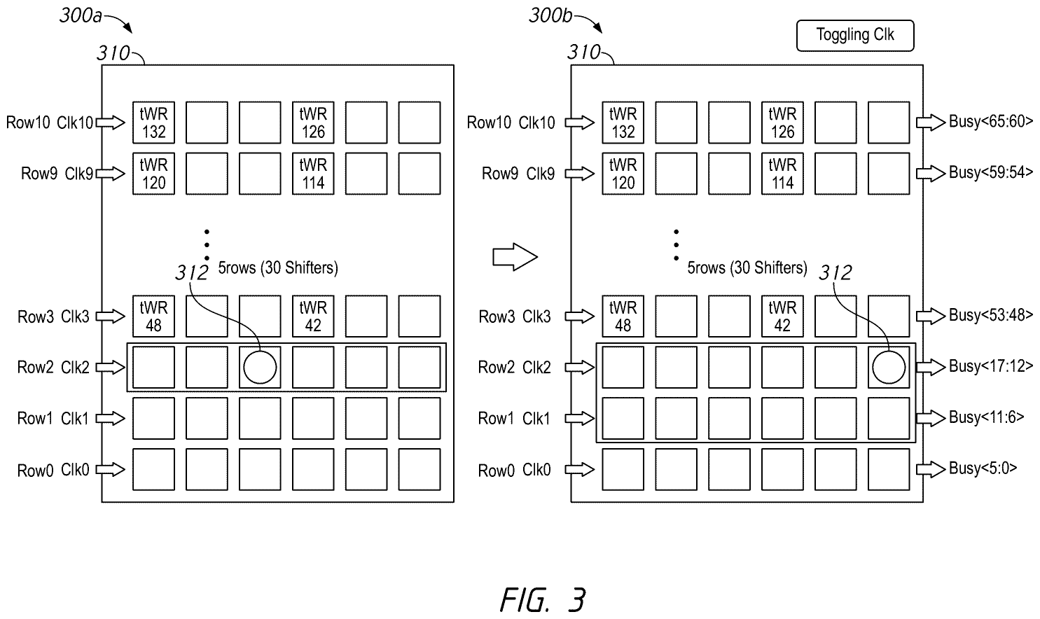

FIG. 3 is a chart of example operations in a latch array of a command shifter according to some embodiments of the present disclosure. The latch array 310 may, in some embodiments, represent an example implementation of the latch array 210 of FIG. 2. In the example implementation of FIG. 3, the latch array is part of a command shifter used for timing tWR as a write auto-precharge command passes through it.

The latch array 310 shows an example implementation with 11 rows of 6 latches each, for a total of 66 latches. Several locations are noted where different settings may be used for durations of tWR, for example tWR 132, tWR 126, and so forth. The settings are noted in clock cycles of the external clock (e.g., CK and/CK of FIG. 1). However the clock signals which are provided to each row may be a divided clock signal (e.g., LCLK of FIG. 1 and/or CLK of FIG. 2) which has half the frequency of the external clock. Accordingly, each latch may represent two cycles of the external clock signal. Other number of latches, other possible values of tWR, and other arrangements of the latch array may be used in other example embodiments.

In the example implementation of FIG. 3, the clock circuits (e.g., 202 of FIG. 2, not shown in FIG. 3) provide a toggling clock signal when the command is in their row or in the final latch of the previous row. FIG. 3 shows a first time 300a and a second time 300b. At the first time, the write auto-precharge command 312 is locate in the third row (Row2), in a latch which is the fourth latch from the end of the row. At the first time 300a, only Clk2, the clock signal for the third row, is toggling. At the second time 300b, the command 312 has advanced three more latches and is now in the final latch of the third row. Accordingly, the clock signals Clk2 and Clk1 for both the third row and second row respectively are toggling. Once the command moves into the second row, the clock signal Clk2 will stop toggling.

The individual latches provide a busy signal Busy which indicates if the command is currently in that latch. For the sake of clarity in the drawing, the busy signals are shown to the right of the array 310 in the second time 300b, however the busy signals are provided at both times 300a and 300b. The busy signals are indexed by the number of the latch which provides that busy signal, counting from the lower rightmost latch (Busy<0>) which in the array 310 is the final latch in the series, backwards along the series. So the busy signal provided by the latch to the left of the final latch is Busy<1> and so forth up to Busy<65>, here shown as the upper leftmost latch of the array 310. At the first time 300a, the busy signal Busy<15> will be active, while the other busy signals will be inactive. At the second time 300b, the busy signal Busy<12> is active while the other busy signals will be inactive. The clock circuits may use the busy signals to track the command 312 as it moves through the array.

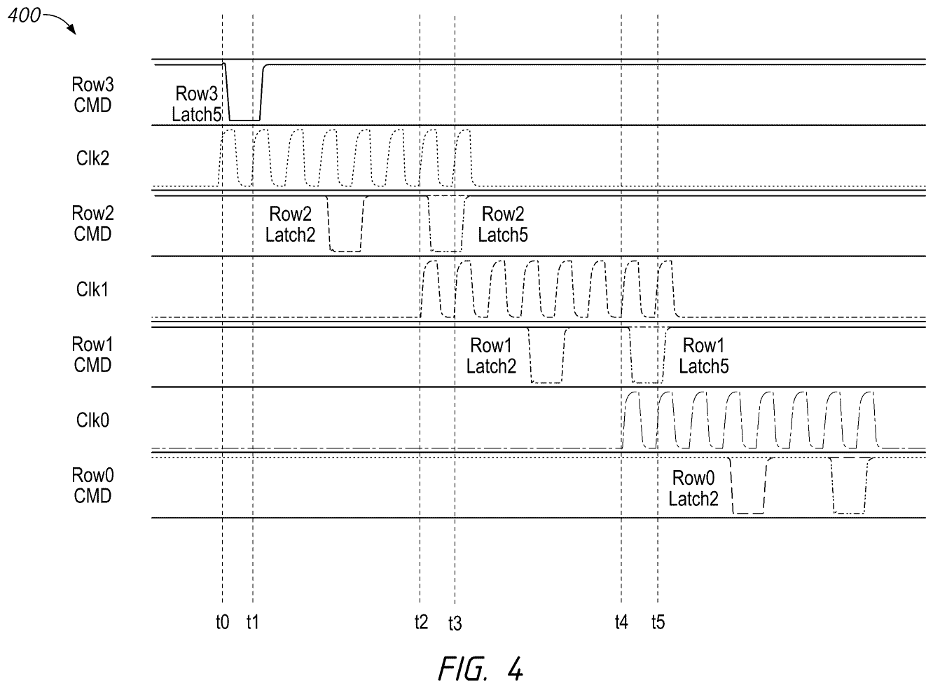

FIG. 4 is a timing diagram of clock signals in a command shifter according to some embodiments of the present disclosure. The timing diagram 400 may, in some embodiments, represent operations in a command shifter such as the command shifter 132 of FIG. 1, 200 of FIG. 2, and/or the array 310 of FIG. 3. Unlike the implementation discussed in the example of FIG. 3, in the example implementation of FIG. 4, each clock circuit (e.g., 202 of FIG. 2) provides a toggling clock signal when the command is in a latch of that row or within the last two latches of the previous row.

The timing diagram 400 shows a set of commands passing through different rows as well as clock signals (e.g., provided by clock circuits) for those rows. The commands and clock signals may represent a portion of the clock signals and commands in the latch array. The timing diagram 400 shows three rows of clock signals (and four rows of commands), each of which includes 6 latches coupled in series, here labelled from 0 to 5, with the first latch on each row labelled 0 and the final latch labelled 5. The waveforms of the timing diagram 400 only shows selected latches within the row, in particular waveforms are only shown for latch 2 (e.g., the third latch along the row) and latch 5 (e.g., the last latch on each row). Since the clock signal for the next row is triggered by the previous latch (latch4), the next clock signal is toggling by the time the signal for Latch5 becomes active.

At a first time t0, the command is output from Row3, Latch5, the last latch of the fourth row (Row3). Before the time to, the busy signal from Row3, Latch4 causes the clock circuit for Row2 to begin toggling the clock signal Clk2. Clk2 toggling starts at least one clock cycle before a second time t1. At the time t1, the output of Row3 Latch5 is latched by Row4 Latch1 by Clk2. Over the next four clock cycles of Clk2, the command gets shifted through the latches of Row2, until at a third time t2, when it is outputted from Row2, Latch5. Since Clk1 begins toggling responsive to the busy signal from the second to last latch (Row2, Latch4), there are two clock cycles where both Clk2 and Clk1 are toggling at the same time. After those two cycles, at the time t2, the command has exited the last latch (Latch5) of Row2, so the clock circuit for Row2 stops providing the signal Clk2 as a toggling clock signal. At a fourth time t3, the command output from Row2, Latch5 is latched by Row1, Latch1. The toggling of Clk1 shifts the command through Row1, until at a fifth time t4, the command is outputted from Row1, Latch5. Similar to the other rows, at least one clock cycle before a sixth time t5, the busy signal from Row1, Latch4 causes the next clock Clk0 to begin toggling. There are two cycles of overlap where both Clk1 and Clk0 are toggling, and the command exits Row1 and enters Row0.

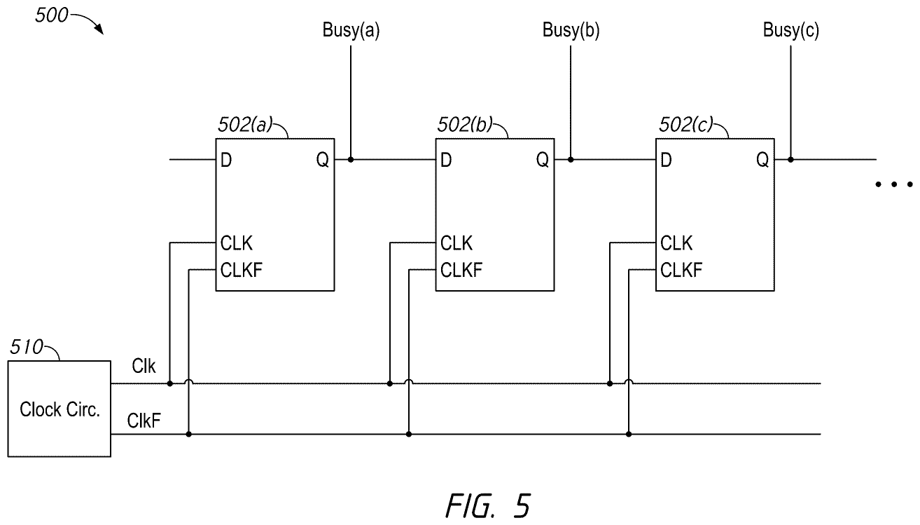

FIG. 5 is a schematic diagram of latches along a row of a command shifter according to some embodiments of the present disclosure. The row 500 may represent a portion of one row of latches in an array of latches in a command shifter, such as the latch array 210 of FIG. 2 and/or 310 of FIG. 3.

The row 500 includes a number of latch circuits 502 (e.g., 212 of FIG. 2), here labelled a, b, and c, and a clock circuit 510 (e.g., 202 of FIG. 2). Each of the latch circuits 502 includes an input terminal D, an output terminal Q and two complementary clock terminals CLK and CLKF. The latches are coupled in series such that an output of latch 502 is coupled to the input of the next latch. For example, the output terminal of latch 502(a) is coupled to the input terminal of latch 502(b), and the output terminal of latch 502(b) is coupled to the input terminal of latch 502(c).

Each of the latches 502 is coupled in parallel to the same clock signals, Clk and ClkF. The signals Clk and ClkF are complementary to each other. The signal Clk is coupled to the clock terminals CLK of the latches 502 while the signal ClkF is coupled to the complementary clock terminals CLKF of the latches 502. Each latch provides a respective busy signal from their output terminals. For example latch 502(a) provides Busy(a), latch 502(b) provides Busy(b) and latch 502(c) provides Busy(c).

When the clock circuit 510 is toggling the clock signals Clk and ClkF, the latches operate 502 to shift data along the serial row of latches. For example, on a rising edge of Clk (and a falling edge of ClkF), each of the latches 502 may latch the value on the input terminal. So if a logical high is applied to the input terminal of the latch 502(a), then on a first rising edge of Clk, the signal Busy(a) will become a logical high. On a second rising edge of Clk, the latch 502(b) will latch the logical high of Busy(a), and the output Busy(b) will become a logical high, while (assuming the input of 502(a) has gone back to being a logical low), the signal Busy(a) will become a logical low.

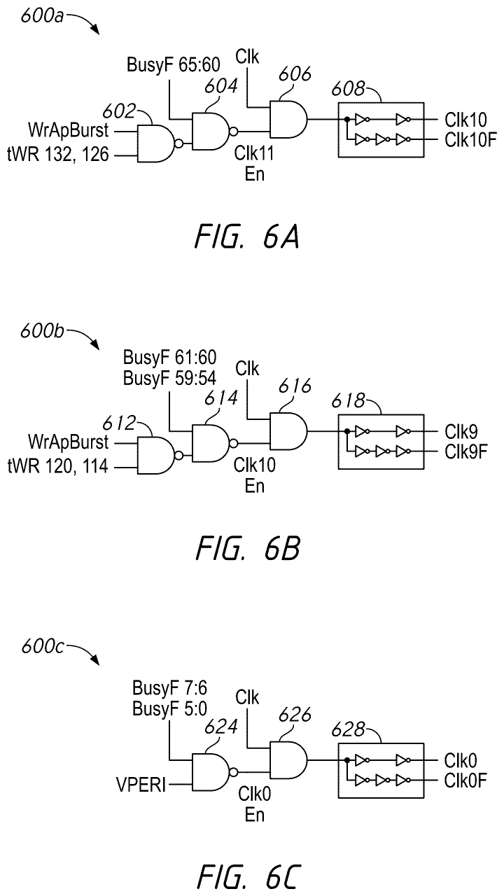

FIGS. 6A-6C are schematic diagrams of clock circuits according to some embodiments of the present disclosure. The clock circuits 600a-600c each represent different versions which may be used to implement a clock circuit which provides clock signals to a row of latches in a command decoder. For example the clock circuits 600a-600c may implement one or more of the clock circuits 202 of FIG. 2 and/or 510 of FIG. 5 in some examples.

Each of the clock circuits receives a clock signal Clk as well as various command signals and provides complementary clock signals ClkL and ClkLF to its respective row when enabled by those command signals. There are different clock circuits 600a, 600b, and 600c, because different clock circuits may receive different signals based on the position of their associated row within the array and whether or not that row can be the row where the command enters the array or not. The clock circuit 600a represents a clock circuit used on an initial row of the array (e.g., a row with no preceding row in the series such as Row10). The clock circuit 600b represents a clock circuit used in a row which is not the initial row, but where the command can initially enter the array (e.g., one of the rows which includes a latch specified by a setting of the mode register, such as Row9). The clock circuit 600c represents a clock circuit used by a row in which the command cannot enter the array (except from a previous row) such as Row0.

For the sake of explanation, example signal names are given in FIGS. 6A-6C to match the example layout used in FIG. 3. The clock circuit 600a represents a clock circuit which may be used on Row10. The clock circuit 600b represents a clock circuit which may be used on Row9 to Row3. The clock circuit 600c represents a clock circuit which may be used on Row2 to Row0. Each of the clock circuits 600a is represented with specific signal names related to a specific row for clarity of explanation. For example, the clock circuit 600a is described with respect to Row11, the clock circuit 600b is described with respect to Row10, and the clock circuit 600c is described with respect to Row0. However, other clock circuits of the same type may be coupled to different signals. Similarly, for the sake of explanation, the clock circuits are described with respect to write commands (e.g., as part of a tWR shifter), however similar clock circuits may be used in an tRTP shifter.

The clock circuit 600a includes a first NAND gate 602 with inputs coupled to a write burst signal WrApBurst and mode register signals tWR132 and tWR126. The signal WrApBurst is active a few clock cycles before the write auto-precharge command (e.g., WrAp) is input to the latch array and stays active until the write auto-precharge command is input to the array. The mode register signals tWR132 and tWR126 represent signals which indicate that the command may enter the array in one of the latches of the row associated with the clock circuit 600a. The output of the first NAND circuit 602 is coupled to one of the inputs of a second NAND gate 604. The other input of the second NAND gate 604 is coupled to a set of busy signals associated with the same row as clock circuit 600a, in this case from latches number 65:60. The latches are consecutively numbered from Latch0, the final latch in the shifter, to Latch66, the latch which is furthest from Latch0. For example, as drawn in FIG. 3, Latch0 would be the bottom rightmost latch, with Latch1 on its left, and so forth up to Latch65 in the upper leftmost corner. The second NAND gate 604 is coupled to inverse busy signals BusyF<65:60> which are at a logical high when those latches do not contain the command and at a logical low when the latch does. The inverse busy signals use the same indexing as the latches which provide them. The second NAND gate 604 provides a row clock enable signal Clk10 En as an output.

Accordingly, the clock enable signal Clk10 En is provided at a logical high when any of BusyF<65:60> is at a logical low (e.g., when the command is within Row 10) or when both the WrApBurst signal is active and the mode register signal tWR132 or tWR126 is active. In other words the signal Clk10 En is provided at an active level when the command is currently in Row11 or when the command is initially entering the array at Row11 (e.g., when both the mode register signal and WrApBurst are active).

The clock enable signal Clk10 En is provided as an input to an AND gate 606. The AND gate 606 has a second coupled to a clock signal Clk as an input. The clock signal Clk may be an internal clock signal (e.g., LCLK of FIG. 1 and/or CLK of FIG. 2) which is a divided clock of an external clock (e.g., CK and/CK of FIG. 1). The output of the AND gate 606 is coupled to a complementary clock generator circuit 608. The complementary clock generator circuit 608 has two branches coupled in parallel, one branch has an even number of inverters and the other branch has an odd number of inverters. When the clock enable signal Clk10 En is active, the AND gate 606 provides the clock signal Clk to the complementary clock generator circuit 608 which provides Clk 10 (from the branch with an even number of inverters) and Clk10F (from the branch with the odd number of inverters).

The clock circuit 600b may be structurally similar to the clock circuit 600a. For example, the clock circuit 600b includes NAND gates 612 and 614 which may be similar to NAND gates 602 and 604 respectively, AND gate 616 which may be similar to AND gate 606, and complementary clock generator circuit 618 which may be similar to generator 608. The gates may be coupled in a similar manner to the clock circuit 600a, except that in the clock circuit 600b, additional busy signals are received as an input to the NAND gate 614. In this example embodiment, the NAND gate 614 receives the busy signals BusyF<59:54> which represent the busy signals of the current row, and busy signals BusyF<61:60> from the last two latches of the previous row (in this case the last two latches of Row10). In that way, the clock enable signal (e.g., Clk9 En) is provided at an active level when either one of the busy signals of the current row is active or when one of the last two busy signals of the previous row is active, or when the command is initially entering the row associated with the clock circuit 600b.

The clock circuit 600c may be generally similar to the clock circuits 600a and 600b, except the first NAND gate is eliminated because the command cannot initially enter the latch array at the row associated with the clock circuit 600c. Accordingly, the clock circuit 600c has a NAND gate 624 (e.g., 604 or 614 of clock circuits 600a and 600b), an AND gate 626 (e.g., 606 or 616 of clock circuits 600a and 600b) and a complementary clock generator circuit 628 (e.g., 608 or 618 of clock circuits 600a and 600b). The NAND gate 624 has a first input coupled to a system voltage VPERI, which represents a logical high and a second input coupled to the busy signals from the same row associated with the clock generator circuit 600c and the last two latches of the previous row. In this case the NAND gate 624 receives busy signals BusyF<7:0>.

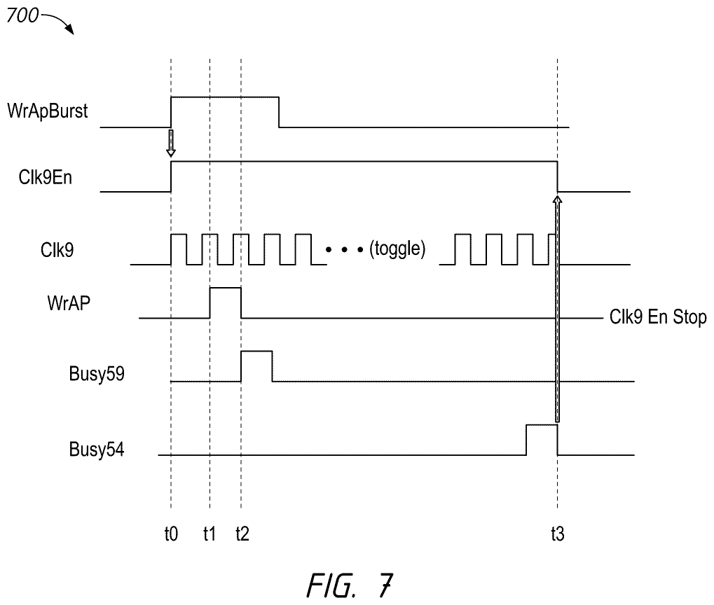

FIG. 7 is a timing chart of example signals in a row of a tWR command shifter according to some embodiments of the present disclosure. The timing chart 700 may, in some embodiments, represent operations of a clock circuit (e.g., 202 of FIG. 2) which operates a row of a latch array (e.g., 210 of FIG. 2 and/or 310 of FIG. 3). For the sake of explanation, the timing chart 700 is described with respect to the same layout and numbering as the example timing chart 310 of FIG. 3. The timing chart 700 represents the operation of a clock circuit associated with a row where the command initially enters the array, for example the clock circuit 600b of FIG. 6. For the sake of explanation, the timing diagram 700 is described with respect to Row10 where tWR 120 is selected in the mode register.

At an initial time t0, a write burst signal WrApBurst becomes active, indicating that a write command is incoming. Responsive to the signal WrApBurst (and the signal tWR 120, not shown, being active), the clock circuit begins providing the clock enable signal Clk10En at an active level. Responsive to Clk10En being active, the clock circuit begins toggling the row clock Clk10. At a second time t1, the write command WrAP is received. Responsive to the next rising edge of the toggling clock signal Clk10, at a time t2, the command is latched by the initial latch (in this case latch 59) as specified by the mode register setting tWR 120. Accordingly, the signal Busy59 becomes active. A time later, at a time t3, the final busy signal in the row, Busy54, becomes inactive when the command leaves the row, and the clock enable signal Clk10En becomes inactive and the clock Clk10 stops toggling.

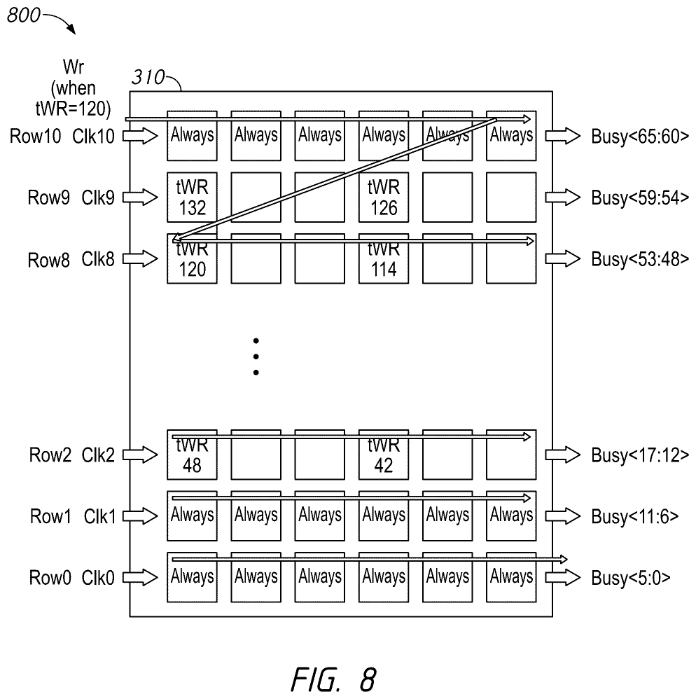

FIG. 8 is a block diagram of a latch array according to some embodiments of the present disclosure. The latch array 800 of FIG. 8 may, in some embodiments, implement the latch array 210 of FIG. 2 and/or 310 of FIG. 3. The latch array 800 shows an alternate arrangement where there is an initial row of latches where the command always enters the array and then the command jumps to a latch specified by the mode register.

For example, FIG. 8 shows arrows which represent the path a command may take through the array 800 when the mode register specifies tWR 120. The command enters the first latch of the initial row (Row10) then passes through the latches of the initial row. When the command reaches the end of the initial row, it passes to the latch specified by the mode register setting. In this example, the command skips over Row 10 entirely, and jumps to the first latch of Row9, which is the latch specified by tWR 120.

Since the initial row in this implementation does not have any mode register setting, the clock circuit for the initial row may be modified compared to the clock circuit 600a of FIG. 6. In particular, in the implementation of FIG. 8, the first NAND gate 602 has input terminals coupled to WrApBurst and VPERI.

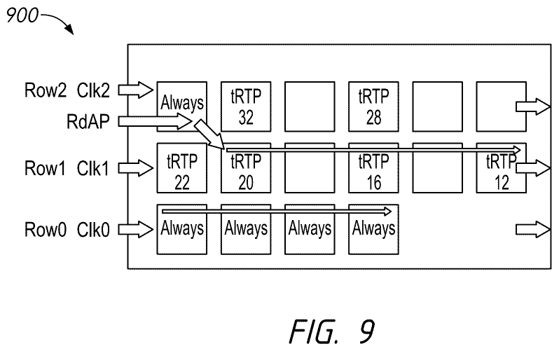

FIG. 9 is a block diagram of a latch array according to some embodiments of the present disclosure. The latch array 900 of FIG. 9 may, in some embodiments, implement the latch array 210 of FIG. 2. The latch array 900 may be similar to the latch arrays 310 of FIG. 3 and/or 800 of FIG. 8, except that the latch array 900 is an example implementation for a tRTP command shifter. The length of tRTP may generally be shorter than the length of tWR, and so an implementation for a tRTP command shifter may have generally fewer latches than an implementation for tWR.

In this example, the command shifter 900 has 3 rows. The top two rows Row2 and Row1 each have 6 latches, while the first row (Row0) has four latches. A command must always pass through first latch of the initial row, and the four latches of the first row. For example, if the mode register specifies tRTP 20 (the second latch of the second row), then as indicated by the arrows, a read auto-precharge command will enter the first latch of the initial row, then jump to the second latch of the second row, pass through the remaining latches of the second row and then pass through the four latches of the first row. In some embodiments, the latches which are marked ‘always’ may be implemented by a different type of latch circuit than the type of latch circuit used to implement the other latches of the array.

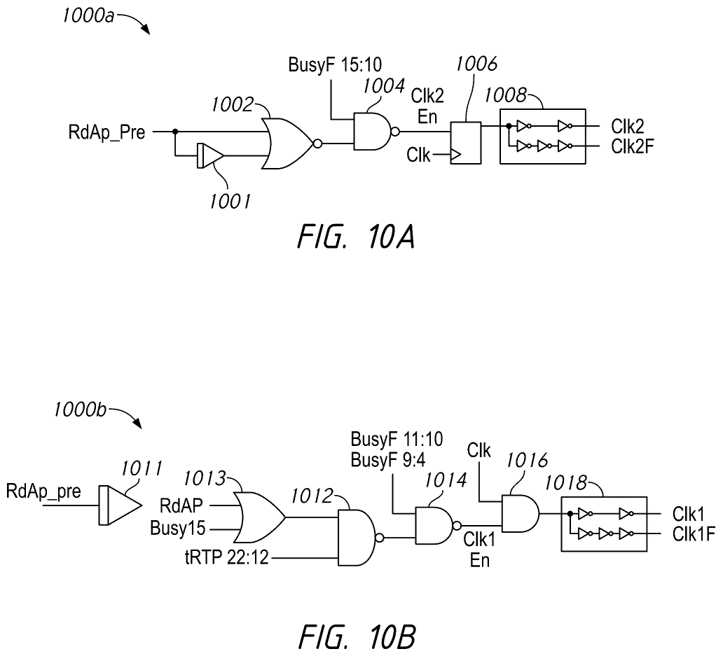

FIGS. 10A-10B are schematic diagrams of clock circuits according to some embodiments of the present disclosure. The clock circuits 1000a and 1000b may, in some embodiments, implement the clock circuits 202 of FIG. 2. The clock circuits 1000a and 100b may generally be similar to the clock circuits 600a-600c of FIG. 6, except that the clock circuits 1000a and 1000b may generally be used in an implementation of a tRTP clock shifter, such as one using the latch array 900 of FIG. 9. For the sake of brevity, certain details and components already discussed with respect to FIG. 6 will not be repeated again with respect to FIG. 9.

The clock circuit 1000a may be used for a row where the command enters the array. Since in this implementation the command always enters the same latch, the clock circuit 1000a may be used to generate Clk2 for Row2 of the array 900 of FIG. 9. The clock circuit 1000b may be used for a row where the command could be directed after the first latch based on a mode register setting. For example the clock circuit 900c may provide Clk1 for Row1 of the array 900 of FIG. 9. Since the command must always pass through the final row (e.g., the first row Row0), while a clock circuit isn't shown in FIG. 10 for the final row, it may be generally similar to the clock circuit described with respect to Clk11/Row11 of FIG. 8.

The clock circuit 1000a includes a first NOR gate 1002 which has an input coupled to a read signal RdAp_pre a second input coupled to RdAp_pre through a delay circuit 1001. The signal RdAp_pre may become active when a read command is received. The signal RdAp_pre is delayed to make the signal RdAp, which is the command that enters the array. The delay between RdAp_pre and RdAp may give a margin to allow the clock circuit to begin toggling the clock before the command enters the array. Accordingly, the output of the NOR gate 1002 may become a logical low. The logical low state of the output of the NOR gate 1002 may be extended by a delay (e.g., from delay circuit 1001) until the busy signal BusyF<15> becomes active (e.g., a logical high) when the Latch15 latches RdAp. The clock circuit 1000a includes a NAND gate 1004 which has a first input coupled to a set of complementary busy signals from the associated row, in this case BusyF<15:10> from Row2 and a second input coupled to the output of the NOR gate 1002. The output of the NAND gate 1004 is the clock enable signal Clk2 En.

Accordingly, when RdAp_pre becomes active, the output of the first NOR gate 1002 will become a logical low for a time, which will cause Clk2 En to become high, regardless of the states of BusyF<15:10>, which will be high before the read command enters the shifter and remain high for a delay time (based on delay circuit 1001) until BusyF<15> becomes active when Latch15 latches RdAp. Once the command does enter the shifter, if it is in any of the latches of the initial row, the complementary busy signals will keep Clk En active. When the command leaves the initial row (causing all of BusyF<15:10> to become a logical high) or when the delay time has passed (whichever is longer), Clk2 En will become inactive again. The row clock enable signal Clk2 En is provided as a data input to a latch 1006. The latch 10006 has a clock terminal coupled to the clock signal Clk (e.g., LCLK of FIG. 1 and/or CLK of FIG. 2). The latch 1006 provides a toggling clock signal when Clk2 En is active to the complementary clock generator circuit 1008 which provides complementary toggling clocks Clk2 and Clk2F.

The clock circuit 1000b may be generally similar, except it has a first NAND gate 1012, and an OR gate 1013 which takes RdAp and Busy15 as inputs and provides an output to one of the inputs of the NAND gate 1012. The first input is a delayed read auto-precharge signal RdAp. A delay circuit 1011 delays the read auto-precharge signal RdAp_pre to generate the delayed read auto-precharge signal RdAp. The OR gate 1013 provides a logical high to a first input of the NAND gate 1012 when either the signal RdAp or the signal Busy 15 are active. The second input of the NAND gate 1012 is coupled to the mode register settings tRTP 22:12 which indicate that the command jumps from the first latch to a latch along the associated row (along Row1). The second NAND gate 1014 has inputs coupled to the output of the first NAND gate 1012, and to the complementary busy signals for the row associated with the clock circuit 1000b (BusyF<9:4>) and the final two latches of the previous row (BusyF<11:10>).

The first NAND gate 1012 will provide a logical low either when RdAp becomes active or when Busy15 becomes active (indicating the command has entered the initial latch), and when the mode register settings indicate that the command jumps from the first latch to one of the latches of the row associated with the clock circuit 1000b. The second NAND gate 1014 provides the clock enable signal Clk1 En at an active level when either the first NAND gate 1012 is providing a logical low, or when one of the complementary busy signals for the current row and last two latches of the previous indicate the command is in one of those latches. The clock enable signal Clk1 En is provided as an input to an AND gate 1016, which also receives Clk as an input, and provides an output to a complementary clock generator circuit 1018. Accordingly, the clocks Clk1 and Clk1F begin toggling when the command is in the current row or the last two latches of the previous row, or when the signals coupled to the first NAND gate 1012 indicate that the command has entered the array and is about to jump to the current row.

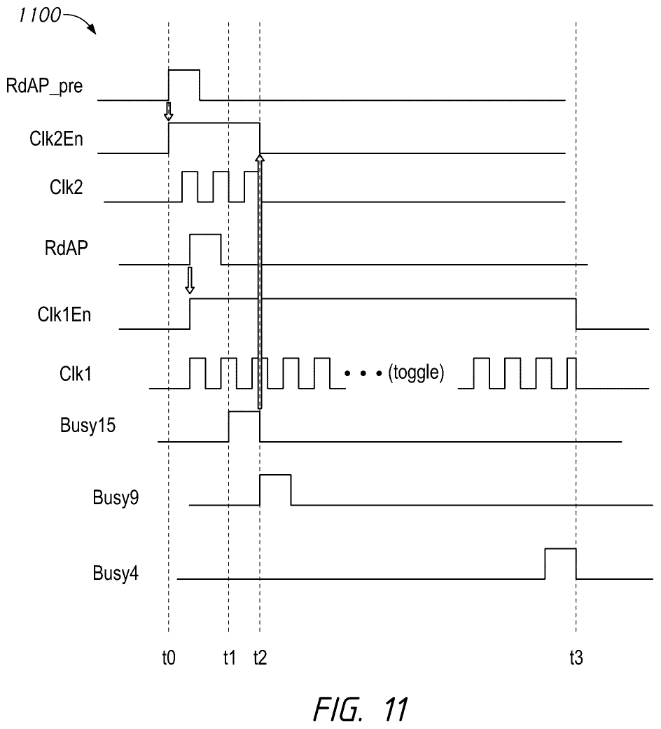

FIG. 11 is a timing diagram of operations in an tRTP shifter according to some embodiments of the present disclosure. The timing diagram 1100 may, in some embodiments, represent operations in a command shifter such as 132 of FIG. 1 and/or 200 of FIG. 2. In particular, the timing diagram 1100 may represent the operation of a tRTP shifter such as the array 900 of FIG. 9 as operated by clock circuits such as those shown in FIGS. 10A-10B. For the sake of consistency, signal names and latch positions shown in FIGS. 9-10B will be used with respect to FIG. 11, and certain details and operations already described previously will not be repeated again.

At an initial time t0, the signal RdAp_pre becomes active to indicate that a read command is about to enter the shifter. This in turn causes the signal Clk2En to becomes active. Just after the initial time (e.g., in synchronization with Clk), the signal Clk2En becoming active causes the clock signal Clk2 to begin toggling. Meanwhile, a delay time after RdAp_pre became active, the delayed signal RdAp becomes active (e.g., as provided by delay circuit 1011 of FIG. 11B). This in turn causes the signal Clk1En to become active and the signal Clk1 to begin toggling, since the mode register settings indicate that the command is about to jump to that row.

At a first time t1, the signal Busy15 becomes active as the read command enters the first latch of initial row of the shifter. At a second time t2, the command moves to latch 9, as indicated by the setting tRTP (in this example tRTP=20). The command moves responsive to a rising edge of Clk1. Since the command leaves latch 15, the signal Busy15 becomes inactive, which in turn causes the clock signal Clk2 to stop toggling. At a later time t0, the command exits the final latch of the second row (Row1) which causes the busy signal Busy4 to become inactive and since no busy signals along that row are active the clock signal Clk1 stops toggling.

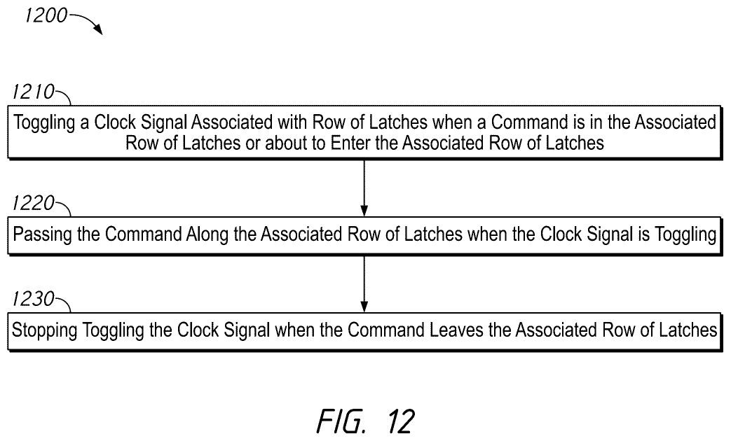

FIG. 12 is a flow chart of a method according to some embodiments of the present disclosure. The method 1200 may, in some embodiments, be performed by one or more of the apparatuses or systems described herein. For example the method 1200 may, in some embodiments, represent the operations of a clock circuit such as 202 of FIG. 2, 510 of FIG. 5, 600a-600c of FIGS. 6A-6C, and/or 1000a-1000b of FIGS. 10A-10B.

The method 1200 may generally begin with box 1210, which describes toggling a clock signal associated with a row of latches when a command is in the associated row of latches or is about to enter the associated row of latches. The row of latches may be a row of latch array such as 210 of FIG. 2, 300a/b of FIG. 3, 800 of FIG. 8 and/or 900 of FIG. 9. The box 1210 may include toggling the clock signal responsive to the command being within N latches of moving to the associated row from a previous row. The previous row may be a row where the command passes from the final latch of the previous row to latch of the current row. The box 1210 may include toggling the clock signal responsive to a signal indicating the command is about to enter the array (e.g., RdAp_pre or WrApBurst) and a setting indicating the command is about to enter in a latch of the associated row (e.g., tWR or tRTP).

The method 1200 may include passing an internal clock signal (e.g., LCLK of FIG. 1 and/or CLK of FIG. 2) as the toggling clock signal. In some embodiments, the method 1200 may include activating a clock enable signal (e.g., Clk10En etc.) responsive to busy signals provided by the latches of the associated row of latches or a busy signal from the final latch of the previous row and toggling the clock signal responsive to the active clock enable signal. The method 1200 may include providing a busy signal from each latch which is active when the command is in that latch and using the busy signals to determine when to activate the clock signals. The method 1200 may include providing a ready pulse READY when the command exits the command shifter.

The method 1200 may include receiving the command as part of an access operation. For example the command may be a read command or a write command. The method 1200 may include entering the command at a starting latch of the latch array. In some embodiments, the starting latch may be determined by a setting, such as a mode register setting (e.g., tWR or tRTP). In some embodiments, one or more starting latches may be predetermined, and the setting may determine which latch is entered after the starting latch(es). In some embodiments, the method 1200 may include skipping one or more latches of the latch array based on the setting (e.g., by skipping from the predetermined starting latch to a latch specified by the setting). Accordingly, the previous row that the command is about to enter the associated row from may not be the directly previous row in the sequence of the shifter.

In some embodiments, the method 1200 may include toggling the clock signal when the command is in the associated row of latches or in one of the final N latches of the previous row of latches. For example, if N is two, then the method 1200 may include toggling the clock signal when the command is in the last two latches of the previous row or in the associated row.

In some embodiments, the method 1200 may include toggling the clock signal responsive to a setting which indicates a latch of the associated row of latches and a signal (e.g., WrApBurst or RdAp_pre) which indicates the command will be entering the latch array. For example, the setting may indicate that the starting latch is in the associated row. The setting may also indicate that the command is about to jump to a latch of the associated row after passing through the predetermined starting latches.

Box 1210 may generally be followed by box 1220, which describes passing the command along the associated row of latches when the clock signal is toggling. The method 1200 may include passing the command from latch to latch with each rising edge of the clock signal when the clock signal is toggling.

Box 1220 is followed by box 1230, which describes stopping toggling the clock signal when the command leaves the associated row of latches. For example, when the command leaves a last latch of the row (or otherwise leaves the row) the clock signal may stop toggling and return to an inactive state (e.g., staying a same level).

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a first row of latches coupled in series, each coupled in common to a first clock signal and configured to pass a command along the first row of latches responsive to the first clock signal toggling;
a second row of latches coupled in series, each coupled in common to a second clock signal and configured to pass the command along the second row of latches responsive to the second clock signal toggling, wherein a first latch of the second row of latches is coupled in series with a last latch of the first row of latches;
a first clock circuit configured to toggle the first clock signal when the command is in the first row of latches; and
a second clock circuit configured to toggle the second clock signal when the command is in the last latch of the first row of latches or one of the latches the second row of latches.

2. The apparatus of claim 1, wherein the first clock circuit is configured to toggle the first clock signal when a setting has a value associated with one of the latches of the first row of latches, and
wherein the second clock circuit is configured to toggle the second clock signal when the value of the setting is associated with one of the latches of the second row of latches.

3. The apparatus of claim 2, further comprising a mode register configured to store the value of the setting, wherein the value of the setting indicates length of shift of the command in the command shifter.

4. The apparatus of claim 1, wherein the second clock circuit is configured to toggle the second clock signal when the command is within N latches of the last latch of the first row of latches.

5. The apparatus of claim 1, wherein the first and the second clock circuit are configured to receive an internal clock signal,
wherein the first clock circuit is configured to provide the internal clock signal as the first clock signal when the first clock signal is toggling, and
wherein the second clock circuit is configured to provide the internal clock signal as the second clock signal when the second clock signal is toggling.

6. The apparatus of claim 1, wherein the first clock circuit is configured to stop toggling the first clock signal when the command exits the last latch of the first row of latches, and
wherein the second clock circuit is configured to stop toggling the second clock signal when the command exits a last latch of the second row of latches.

7. The apparatus of claim 1, wherein the first row of latches and the second row of latches are part of a command shifter of a memory, and wherein the memory is configured to provide ready pulse when the command exits the command shifter.

8. An apparatus comprising:
a latch array comprising a plurality of latches coupled in series, wherein the plurality of latches are arranged in a plurality of portions;
a plurality of clock circuits, each associated with one of the plurality of portions and configured to provide a respective one of a plurality of clock signals to the associated one of the plurality of portions, wherein each of the plurality of clock circuits is configured to toggle the respective one of the plurality of clock signals responsive to a command being in one of the plurality of latches which is part of the associated one of the plurality of portions or about to enter the associated one of the plurality of portions.

9. The apparatus of claim 1, wherein the plurality of clock circuits are configured to toggle the respective one of the plurality of clock signals responsive to the command being within N latches of the final latch of the previous one of the plurality of portions.

10. The apparatus of claim 1, wherein the command is a read auto-precharge command and the latch array is part of an tRTP shifter or the command is a write auto-precharge command and the latch array is part of a tWR shifter.

11. The apparatus of claim 1, wherein each of the plurality of latches is configured to provide a respective one of a plurality of busy signals at an active level when the command is in the respective one of the plurality of latches.

12. The apparatus of claim 11, wherein each of the plurality of clock circuits is configured to receive a portion of the plurality of busy signals provided by the associated one of the plurality of portions.

13. The apparatus of claim 8, wherein selected ones of the plurality of clock circuits are additionally configured to begin toggling the respective one of the plurality of clock signals responsive to a setting indicating a latch in the associated one of the plurality of portions and a command signal indicating the command is about to enter the latch array.

14. The apparatus of claim 13, further comprising a mode array configured to store the setting, wherein the setting indicates a length of shift of the command in the latch array.

15. A method comprising:
toggling a clock signal associated with a row of latches of a latch array of a command shifter when a command is in the associated row of latches or about to enter the associated row of latches;
passing the command along the associated row of latches when the clock signal is toggling; and
stopping toggling the clock signal when the command leaves the associated row of latches.

16. The method of claim 15, further comprising toggling the clock signal responsive to a setting indicating one of the latches of the associated row of latches and a signal indicating the command is about to enter the latch array.

17. The method of claim 15, further comprising passing an internal clock signal as the toggling clock signal.

18. The method of claim 15, further comprising:
activating a clock enable signal responsive to busy signals provided by the latches of the associated row of latches or a busy signal from a final latch of the previous row of latches; and
toggling the clock signal responsive to the active clock enable signal.

19. The method of claim 15, further comprising skipping one or more latches of the latch array responsive to a setting.

20. The method of claim 15, further comprising providing a ready pulse signal when the command exits the latch array.
